(19) United States
(12) Patent Application Publication
(10) Pub. No.: US 2015/0194939 A1
(43) Pub. Date: Jul. 9, 2015

(54) MEANS FOR DYNAMIC ELECTRONIC OR DIGITAL PROGRAMMABLE CONTROL OF ANALOG HIGH OR LOW VOLTAGE AUDIO SIGNALS IN MUSIC INSTRUMENT AMPLIFIERS

(71) Applicants: Matthew Loren Beeson, Baton Rouge, LA (US); Bradley Kenneth Beeson, Phoenix, MD (US)

(72) Inventors: Matthew Loren Beeson, Baton Rouge, LA (US); Bradley Kenneth Beeson, Phoenix, MD (US)

(21) Appl. No.: 13/659,711

(22) Filed: Oct. 24, 2012

(51) Int. Cl. H03F 3/183; H03F 3/08; H03F 3/02

(52) U.S. Cl. CPC H03F 3/183; H03F 3/02; H03F 3/085; H03F 2200/03

(57) ABSTRACT

A method for providing digital or electronic control, using electrical isolation or optical decoupling devices, of an analog music instrument amplifier, whether vacuum tube or transistor based, that allows real-time or digitally programmable control over the analog circuitry of said music instrument amplifiers, without altering the currently available form factors or audio qualities of said amplifiers is provided.

### CROSS REFERENCE TO RELATED APPLICATIONS

Not Applicable

### FEDERALLY SPONSORED RESEARCH

Not Applicable

### REFERENCE TO SEQUENCE LISTING

Not Applicable

### FIELD

The present invention relates generally to tube and transistor analog music instrument amplifiers. The present invention relates more particularly to music instrument tube amplifiers. The present invention relates most specifically to tube amplifiers for the amplification of electric guitars.

The present invention solves the issue of providing digital or electronic control of a music instrument amplifier, whether vacuum tube based or transistor based, without altering common form factors or sound quality of the amplifier.

### BACKGROUND

Electric guitars require amplification to be useful. Vacuum tubes and transistors are both electrical signal amplifiers. The term “amplifier” in that sense refers to the actual tube or transistor. Simply stated, they increase the voltages (such as the very small voltages generated by an electric guitar) applied to them. The term “amplifier,” when referring to guitar amplifiers in the guitarist's vernacular, however, typically refers to a device that includes the tubes and/or transistors, internal wiring and/or circuit boards, power supply, transformers, enclosure, etc. The term likewise could refer to what is called the “combination” or “combo amp,” which would also include an integrated loudspeaker or speakers. Guitar or instrument amplifiers are generally available in three topologies. One topology involves digital “modeling” to achieve particular sounds. The sonic characteristics of various guitar amplifiers may be stored as digital information, and applied to incoming guitar signals, which undergo an analog to digital conversion at the input to the amplifier. The desired sound, once dialed in by the user, is then output at usable volume level, ultimately either via tubes or transistors at the power amplifier stage to achieve the required voltages to generate the mechanical force required to excite a loudspeaker transducer. The other two are based on the type of preamplifier device employed by the guitar amplifier design, which could be either a transistor or a vacuum tube.

Digital modeling amplifiers are the most flexible guitar or music instrument amplifiers. They incorporate digital effects as well as tone shaping all in one package. A guitar, e.g., is plugged into the unit, and its low-voltage output immediately undergoes an analog-to-digital conversion. The guitar signal becomes binary code. Just as text can be copied and pasted in the digital realm, and photos and 3D renderings can undergo remarkable and apparently infinite changes, audio signals can be twisted, mixed, copied, and altered in any way the programmer working for the amplifier manufacturer can imagine.

Manufacturers “modeled” the sounds of various popular or legendary guitar amplifiers, and can digitally apply these sonic signatures to the guitar signal. In theory, the modeling amp can sound like a classic tube amp, but just as polyester fibers may mimic natural fibers, they are not natural fibers, and a digital modeling guitar amplifier is not a tube amplifier. Ultimately, a digitally applied “model” cannot be a tube circuit any more than oil can be cotton.

Transistor instrument amplifiers (particularly those using transistors in the preamplifier stage) are popular and widespread due to low cost, durability, and even light weight. However, they simply do not sound very good due to the inherent characteristics of transistor operation. Transistors are more efficient than vacuum tubes. They respond very quickly to signals driven into clipping at the preamp stage. Clipping at this stage is often desirable to achieve sounds characteristic in modern rock or similar styles. The inherent speed and efficiency with which the transistor handles signals causes the clip to be very abrupt. That is, compared to an overdriven (and therefore clipped) tube signal, the waveform of an overdriven transistor signal will look more like a square wave on an oscilloscope. The signal overdriven by a tube preamplifier will display more rounded edges at the headroom limit on the oscilloscope. Other reasons exist regarding the sonic preference to tube amplifiers, but suffice to say, transistor-based instrument amplifiers sound inferior to tube-based instrument amplifiers.

Tube-based instrument amplifiers remain the professional choice, particularly for guitar players. Tube guitar amplifiers, in comparison to the others, are more fragile, require regular maintenance, typically weigh more, and are nearly universally more expensive. Compared to transistors, tubes, electrically speaking, are inefficient and slow. Much of the power required to operate a tube is dissipated as heat as opposed to electronic or acoustic energy. They also respond more slowly than transistors in dealing with incoming signals. The desirable side effect of slower response times and less efficiency is a sonic characteristic that musicians and audiophiles call “warmth” or “musicality.” Transistors cannot reproduce it. Because transistors are not tubes. Neither are computer models.

The present invention provides a means to control the analog audio signals in instrument amplifiers, though the most important application, due to the high voltages present, is in vacuum tube music instrument amplifiers. The typical control means currently are knobs (analog potentiometers), switches, and foot-operated switches. Other means have been attempted, but have serious limitations that compromise the intended device, either in cost, weight, design, reliability, efficacy, etc.

One of the most significant attempts was U.S. Pat. No. 5,208,548, filed 1992, Programmable Controls for Vacuum Tube Preamplifier. This invention attempted to provide programmable controls to an analog audio circuit in a tube preamplifier by replacing analog potentiometers with light dependent resistors (LDRs), and associated analog electrical circuitry to provide feedback to the LDRs in an attempt to achieve the correct attenuation values. The design requires a much larger number of discrete parts in comparison to the traditional analog potentiometers, and is therefore larger, more complicated, and significantly more expensive to produce. That patent mentioned prior art that attempted to deal with the issue of providing digital control over tube amplifiers that contemplated voltage-controlled amplifiers (VCAs) and even digitally controlled stepper motors to physically turn the analog potentiometer knobs. VCAs, according to the patent, were unable to accommodate the high voltage signals in a tube amplifier, and the stepper motors proved costly and complicated to implement as well. The patent did not specifically cite the patent numbers of those examples in its discussion of prior art. None of these earned any serious consideration in the marketplace.

U.S. Pat. No. 5,977,474, Continuously Variable Circuit for Producing an Output Signal Having a Continuously Variable Amount of Clean and Distorted Signals, may offer control of the sound of an instrument amplifier, but is nothing more than a pan pedal, the outputs of which feed two discrete channels of an amplifier unit. See abstract, U.S. Pat. No. 5,977,474. It offers no control of the amplifier's gain structure or other parameters, such as tone. The purpose of a pan pedal is indeed to pan the output of an instrument between two separate inputs such as those on instrument amplifiers. Panning between two separate amplifier units was in practice well before the patent was issued. Such methodology offers control of panning between two sounds, but does not control any part of the gain structure in an amplifier, amplifier channel, or other type of device input as the present invention does.

Gain is applied voltage. The above-referenced does not control gain, but rather sends signal in varying degree to one of two amplifier channels. The present invention contemplated a panning type of strategy, but abandoned it over safety concerns. Controlling input gain to an amplifier channel may be achieved with the volume knob of the input device (guitar, for example). Controlling output of a tube typically is achieved with analog potentiometers. The present invention considered a pedal that used potentiometers. The output of a typical instrument preamplifier tube is measured in voltages that are unsafe. One might expect to see an average DC voltage output from a typical instrument preamplifier tube around 125V, ranging anywhere between 30 and 250V, application and use depending. To send such a signal to a pedal introduces legitimate and unacceptable danger to the user. Power amplifier tubes present an even greater danger.

U.S. Pat. No. 4,495,640, Adjustable Distortion Guitar Amplifier, addresses being able to adjust the amount of distortion present in the final signal by a mixing of two channels such that one channel is fed back to the second channel in varying degrees to varying effect. See abstract, U.S. Pat. No. 4,495,640. It also places a parametric e.q. and phase shift, via signal delay in the upstream channel, and provides switches to introduce or remove these various features from the signal chain. The present invention does not add or subtract features to a circuit. It provides dynamic constantly variable control of the gain structure of a standard tube amplifier circuit. It also provides for programmability and other features not contemplated by U.S. Pat. No. 4,495,640.

U.S. Pat. No. 5,789,689, Tube Modeling Programmable Digital Guitar Amplification System provides the digital modeling of a tube guitar as mentioned above. See abstract, U.S. Pat. No. 5,789,689. While approximating the sound of a tube guitar amplifier and providing multiple control interface options, this patent does not contemplate control of a tube amplifier, or indeed, an analog device.

U.S. Pat. No. 6,140,870, Hybrid Thermionic Valve and Solid State Instrument Amplifier, provides a method of combining transistors and tubes into one amplifier circuit. See abstract, U.S. Pat. No. 6,140,870. Dynamic control is not contemplated. Moreover, the present invention, while offering a method that can dynamically control a circuit such as that described in U.S. Pat. No. 6,140,870, will also control an instrument amplifier with an “all-tube” circuit design.

The most recent and most relevant prior art is U.S. Pat. No. 8,204,254, B2, Vacuum Tube Preamplifier, Amplifier and Method for Musical Instruments with Programmable Controls. This patent attempts to provide control of analog tube guitar circuitry employing digital potentiometers. See Summary of the Invention, U.S. Pat. No. 8,204,254. Said invention seeks to replace analog potentiometers with digital potentiometers. “The digital potentiometers are connected to circuitry that is connected directly between the output and input of successive tube stages. Further, the present invention provides for the handling of a +/−15V signal range of the digital potentiometers and the low resistance, 100 k ohms, of the digital potentiometers.” (Sec. 5, Summary of the Invention)

The present invention employs optical decouplers to control features of a circuit. It does not replace analog potentiometers with digital potentiometers, which conduct electrical signals. The present invention contemplated said method, and determined that it is unclear that digital potentiometers are appropriate for the high voltages present in a vacuum tube instrument amplifier, even if they might work in a configuration with transistor preamps outputting much lower voltages. Voltages present at the output of a tube guitar amplifier can range from averages of 30 to 250V, depending on application, circuitry, and other variables. The upper end of digital potentiometer tolerance seems to be around +33V according to digital potentiometer manufacturers and suppliers at the time of this writing. Moreover, the digital potentiometer conducts signal, unlike optical decouplers, which introduce no different analog components to existing circuit designs. Voltages present in a vacuum tube instrument amplifier, and especially in vacuum tube guitar amplifiers will likely cause either audible signal distortions, thermal wear on the digital potentiometers, or failure altogether.

Using optical decouplers, any part of the gain structure at any location in the signal path may be controlled without altering any part of the hardware structure of the circuit. This could be preamp gain, a tone control, a presence control, output volume, or other. The gain structure of the simplest single tube circuit may be controlled, using optical decouplers to apply or attenuate gain at any location, input or output stage. Likewise, optical decouplers may be employed at any location in the signal path, thus offering control of any part of the most complex instrument amplifiers. The optical decoupler allows programmable control over any stage of existing analog circuitry with no modifications to the to circuitry. The optical decouplers, in turn, may be controlled by knobs, foot pedals, software interface, or any other control interface imagined to control a digital device.

Therefore, it is a feature of the present invention to offer dynamic user control or programmable electronic or digital control of an analog music instrument amplifier, whether tube or transistor, without altering common form factors or sound quality of the amplifier.

It is a feature of the present invention to offer dynamically variable user control of an analog music instrument amplifier, tube or transistor, using a foot-operated rocker pedal without altering common form factors or sound quality of the amplifier.

It is a feature of the present invention to offer digital programmable control of an analog music instrument amplifier, tube or transistor, using any digital control protocol, whether MIDI, show control software, or other without altering common form factors or sound quality of the amplifier.

It is a feature of the present invention to offer replication of digital control signals to allow control of multiple amplifiers at the same time, offering dynamically variable electronic or digital user control and programmable control of stereo or multiple analog vacuum tube or transistor music instrument amplifier units at the same time.

It is a feature of the present invention to offer dynamically variable electronic or digital user control and programmable control of multiple channels of a music instrument amplifier, tube or transistor, allowing for the channels to be mixed or alternatively, panned between.

It is a feature of the present invention to offer digitally storable preset information for control of analog tube or transistor music instrument amplifiers.

### BRIEF SUMMARY OF THE INVENTION

The invention is an analog music instrument amplifier, the normally controllable features of which (gain, tone, volume, etc) are controlled using optical decouplers. In the preferred form of the current invention, the analog circuitry currently employed in the state of the art of music instrument amplifiers remains unchanged, as do the standard controls currently available (knobs, switches, etc.). The optical decouplers fully isolate all analog electrical signals from the amplifier to the control protocol, whether rocker foot pedal, software, MIDI or other.

In one form, the invention provides real time control of preamp gain in a tube guitar amplifier via a rocker foot pedal. Necessary for safe operation is that tube guitar amplifier signals not be sent to the pedal, as the signals in a tube guitar amplifier contain unsafe voltages. The present invention in the form using a foot pedal to control preamp gain decouples control signals from the amplifier preamp signal via the use of a low voltage potentiometer in the pedal, such as found in a typical volume pedal, and LED optical decouplers in a digitally controlled control circuit that fully isolates the control circuit from the high voltage amplifier signal. The position of the wiper in the potentiometer in the volume pedal may be referenced to a program stored on a microchip housed in the amplifier enclosure, which then sends a command signal to the decoupler device.

The most basic sound options in tube guitar amplifiers usually come in one of two forms. Either a single channel configuration provides the addition or subtraction of resistors to achieve certain gain levels with the flip (or the stomp) of a switch, thus allowing the electric guitarist or instrument player to change between more or less clipped signals (clean or dirty sounds). Alternatively, some guitar amplifiers employ multiple discrete channels to achieve different tones. Some are as complex as four channels, each with its own boost switch. The pedal boards are large and cumbersome, and the result is still an abrupt switch between tones.

The present invention provides a way to seamlessly fade from tone to tone whether in a single channel, or multi-channel tube or transistor music instrument amplifier topology. Since the LED isolators are digitally controllable, the user control interface may vary. It might be a simple analog foot rocker pedal, like a volume pedal. A digital device in the amplifier would sense the resistance value in the potentiometer, and reference to a table, which then, via stored programming, would direct the output of the LED isolator. Alternatively, a rocker pedal that serves as a MIDI controller could be integrated. Or a show control software application that operates MIDI commands such that changes in the guitar tones can be automated, freeing the musician to focus on something other than when/how to adjust the gain of the amplifier.

Since the control circuitry is digitally commanded, those commands may be copied and sent to multiple amplifiers as well. For the first time, the gain structure of two amplifiers may be controlled dynamically, such that stereo effects will apply to both left and right amplifiers in like proportion to the preamp gain of each amplifier.

### BRIEF DESCRIPTION OF THE DRAWINGS

FIG. 1 Is a block diagram illustrating control of a vacuum tube music instrument amplifier through means of a user control such as a foot operated rocker pedal.

FIG. 2 Is a block diagram illustrating control of a vacuum tube music instrument amplifier through means of a user control such as a foot operated rocker pedal, with the addition of a studio controller.

FIG. 3 Is a block diagram illustrating control of a stereo vacuum tube music instrument amplifier set up through means of a user control such as a foot operated rocker pedal, such that both amplifiers in the stereo set up respond identically in a “master/slave” configuration to the control input.

FIG. 4 Is a block diagram illustration showing the use of a foot operated rocker pedal to control the gain structure of a single channel music instrument amplifier.

FIG. 5 Is a block diagram illustration showing the use of a foot operated rocker pedal to control the mix between two discrete music instrument amplifier channels.

FIG. 6 Is a schematic drawing illustrating the fully isolated electronically controllable variable resistor employing optical decoupling device.

FIG. 7 Is a schematic drawing illustrating the use of fully isolated electronically controllable variable resistor employing optical decoupling devices in a multi-channel application.

FIG. 8 Is a schematic drawing illustrating an example of an all tube music instrument amplifier circuit with a single signal path or channel, employing the fully isolated electronically controllable variable resistor using optical decoupling device.

FIG. 9 Is a schematic drawing illustrating an example of an all tube music instrument amplifier circuit with two channels or discrete signal paths employing the fully isolated electronically controllable variable resistor optical decoupling device in order to mix the sounds from both channels.

### DETAILED DESCRIPTION OF THE INVENTION

The invention is the use of optical decouplers in music instrument amplifiers to fully electrically isolate control protocols from the amplifier, and to leave currently existing circuit designs (and therefore sound qualities) unchanged. Further, said use of optical decouplers will enable either digital or electronic dynamic control as well as programmable control of the analog signal at whatever point in the signal path said optical decouplers are placed. Lastly, as control signals and/or commands may be digitized, they may be replicated and sent to multiple music instrument amplifiers simultaneously.

The present invention provides an improved or at least an alternative variable resistor. In broad terms, the invention comprises a variable resistor system comprising:
a pair of series-connected photo-resistors;
a pair of LEDs to drive the photo-resistors;
a pair of current control circuits to drive the LEDs;

In the preferred form, said photo-resistors are connected serially forming a resistor divider network. The total resistance of said resistor divider network is equal to the sum of the two photo-resistor resistances at any instant in time. The resistance of said photo-resistors is controlled by their corresponding LEDs. By variably adjusting said LEDs, the total resistance of said photo-resistor network can be modified, as well as simultaneously adjusting the resistance at the junction between said photo-resistors relative to either remaining said photo-resistor lead. Adjustment of said LEDs is accomplished with current control circuitry. Said current control circuitry may be actuated either by real-time user control, such as foot operated rocker pedal or switch, or in digitally-stored format such as show control software, or digitally actuated real-time controls such as MIDI. Commanded signals or information provide complimentary commands to said photo-resistors.

In an alternate form, said photo-resistors are connected serially and ganged together to produce a multi-channel variable resistor having independent high-voltage, fully isolated resistor divider networks. The photo-resistors are arrayed in high-side and low-side arrangements having two or more high-side LEDs connected serially and two or more low-side LEDs connected serially, thus enabling control of said photo-resistors by a single high-side current controller and single low-side current controller.

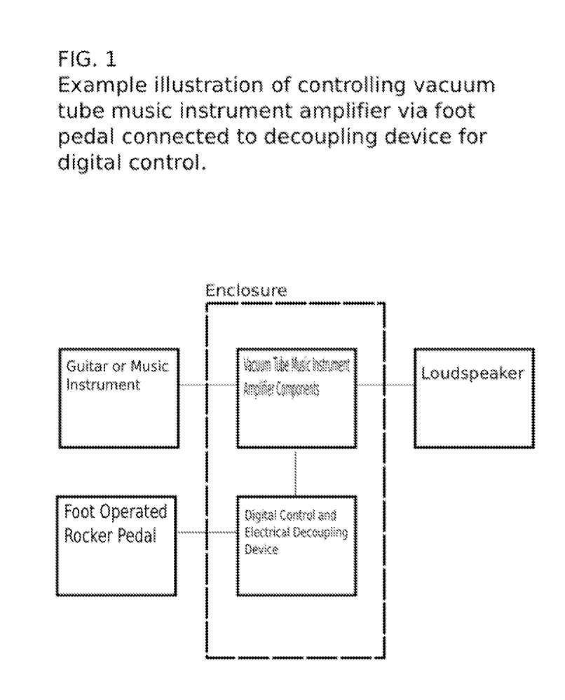

FIG. 1 illustrates one possibility. In this example, a single-channel tube guitar amplifier is used to amplify and shape the tone or sound of an electric guitar input. A foot operated rocker pedal is used for control. A single channel tube guitar amplifier is often represented in marketing as “two channel,” but in reality only contains one signal path. More correctly, the amplifier has two sounds or two gain settings, often referred to as “clean” and “dirty.” The two sounds are achieved with the use of resistors that help prevent or suppress clipped signals on the clean “channel.” Control of introducing or removing the resistors from the path is effectuated by a switch on the amplifier unit itself and often through a footswitch that duplicates the function of the switch.

The current invention provides a variable resistor using optical decouplers that are controlled by the foot rocker pedal. The wiper position of a standard foot rocker pedal, such as found in any volume pedal currently available is sent down a wire to the control device in the amplifier and referenced in digitally-stored tables on a microchip inside the amplifier enclosure to create a command signal to the optical decoupler. In this way, transitions from “clean” to “dirty” are now continuously variable. The musician can add a little or a lot of gain to the signal based on the foot pedal position, thus allowing for a multitude of tone options, or clean fades from one sound to the next, as opposed to the immediate change of tones currently available through hard switching.

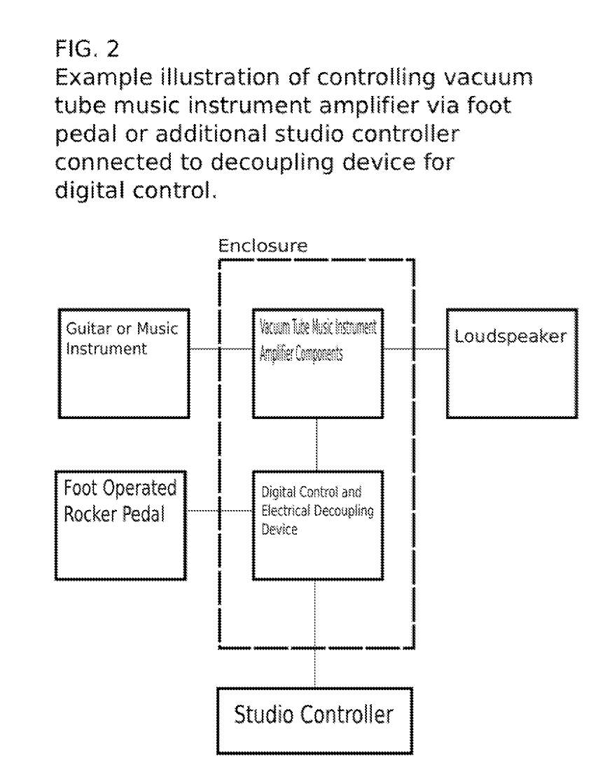

FIG. 2 illustrates a second control possibility, though anyone familiar in the art will immediately recognize that control possibilities abound, since the optical decouplers receive their control or command signals digitally. In FIG. 2, we see a configuration similar to that of FIG. 1, but with the addition of a “studio controller.” This could be a MIDI control device, such as an external fader controller for studio recording software, or it could be a direct MIDI interface that is operated from show control software. In reality, any digital control protocol may now be employed, however practical or impractical.

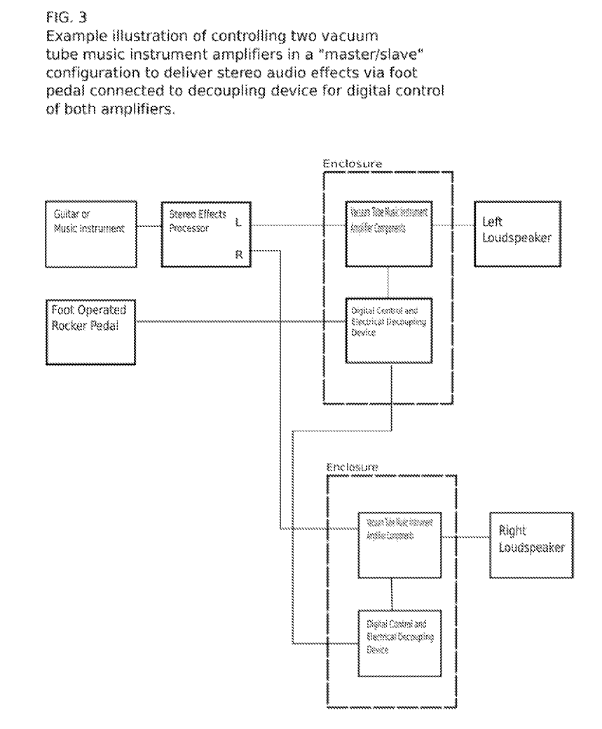

FIG. 3 illustrates an important application of the control device employed by the current invention, that being a “master/slave” arrangement of two amplifiers. Since control commands are digitized in the Digital Amplifier Control System shown in FIG. 3, they may be copied and sent to multiple amplifiers. The illustration shows the use of a stereo effects processor in a stereo guitar amplifier set up. Time based effects processors copy input signals and change their time relationship to that of the original signal resulting in delays, echoes, choruses, flanges, etc. The outputs of such effects may be sent to two different channels in a stereo configuration to achieve very dramatic and interesting sonic results. Sending stereo outputs from effects to two amplifiers to achieve true stereo sound is a simple enough concept. However, changing “channels” or sounds in the amplifiers at the same time has been difficult or impossible. Many channel switching pedals have indicator lights, and many products have multiple channels with associated boosts and indicator lights. Splitting power feedbacks to indicator lights plus channel switches to a stereo configuration would require significant engineering, and would still result in a hard, immediate switch of sounds. The present invention as shown in FIG. 3 may copy control signals at the first Digital Amplifier Control System and send to the second one, which would operate in “slave” mode to the first. Smooth transitions from one sound to the next may be controlled by the foot pedal, and both amplifiers will operate in unison, thus preserving the stereo imaging output by the effects unit while the amplifiers both changed sounds.

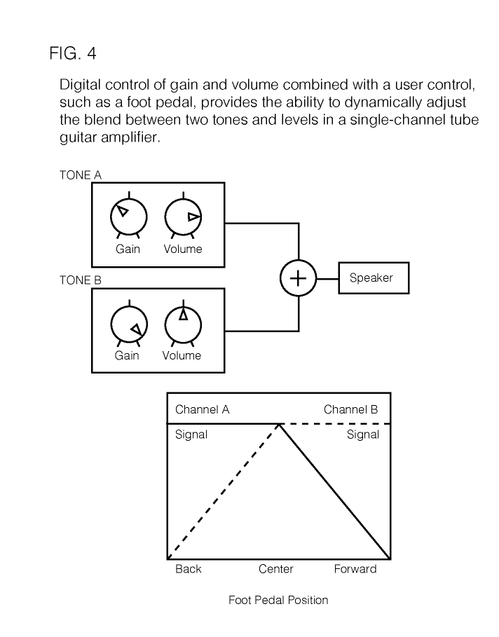

FIG. 4 illustrates how a foot operated rocker pedal or currently available volume pedal, for example, may be used to control the sound in a single channel amplifier with no alteration to existing controls. Recall that many instrument or guitar amplifiers having a single signal path are labeled as “two channel” amplifiers. In reality, they offer two sounds, typically “clean” and “dirty” achieved across one channel with the addition or subtraction of resistors in the circuit. What most such amplifiers label “channels” on the front panel, FIG. 4 calls “Tone” for the sake of clarity. Each “channel” or “tone,” as labeled in FIG. 4, has an accompanying gain and volume knob. Typically, the gain knob is used to adjust the amount of gain or clipping present in that sound, and the volume knob is used to control actual volume or acoustic energy output by a speaker transducer. The present invention requires no modification to this methodology, and a control device, such as a pedal as shown in this figure, may be used to fade between these two sounds, thus achieving a wider variety of tones available to the musician, as well as the ability to fade between sounds, rather than to be limited to a hard switch between them.

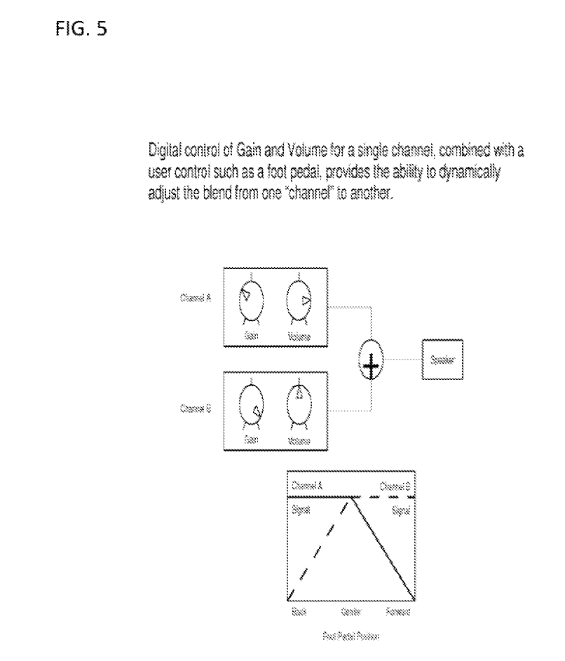

FIG. 5 illustrates how a foot operated rocker pedal or currently available volume pedal, for example, may be used to control the sound in a dual channel amplifier with no alteration to existing controls. In this example, the figure assumes the use of an instrument amplifier using two discrete signal paths to allow for two different sounds, normally user selectable by a foot switch in addition to a switch on the amplifier unit. The present invention allows for a seamless fade between the two channels. The optical decouplers could be used in mixing circuitry, or could be configured as pan controls between the two channels. In either case, normal operator controls, currently available, require no modifications, and control protocol could be a foot operated rocker pedal, such as any currently available volume pedal, or any other digital control protocol. The pedal, for example, could be used to control the mix of the two channels in a continuously variable way, or to pan between the two channels in a continuously variable way thus allowing for a greater variety of sound options available to the musician or a smooth fade between the two sounds, rather than a hard switch between them.

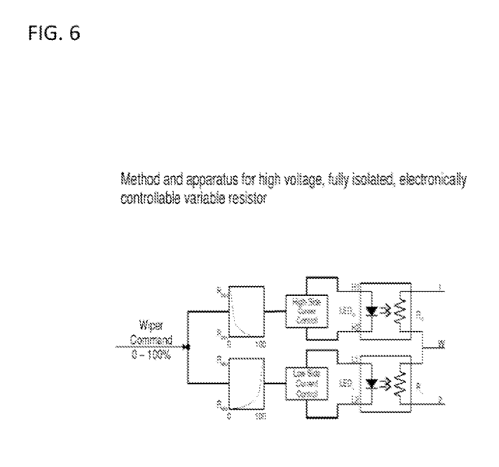

FIG. 6 details the optical decoupling device. This device is incorporated into an analog amplifier circuit in place of a potentiometer for control of circuit gain or volume, or even audio tone. A control element, such as a volume pedal, provides a wiper command to a digital control circuit, which converts the control element input from analog to digital, and uses this digital value to look up complementary values in a microchip housed in the amplifier enclosure for high-side and low-side current controls. The current controls drive analog current through the high side LED_{H} and low side LED_{L}, based on the complementary high-side and low-side values, thereby smoothly and continuously affecting the resistance of the light-sensitive resistors R_{H} and R_{L} in a manner reminiscent of the heretofore-replaced potentiometer. In addition, other digital control protocols may be employed, such as MIDI, control software, or any other digital control method.

This device provides a flexible means of controlling any part of the gain structure of a standard analog music instrument amplifier circuit with digital precision. The lookup table can be constructed to approximate any number of functions to accommodate linear taper or audio taper, or any other type of taper, to provide the most ear-pleasing or practical (or even impractical) manipulation of gain structure characteristics as the control element is moved through its range of motion or digital commands are received. Further, the lookup table can be tailored specifically to change the characteristic impedance of the optical decoupling device from one total resistance value to another, such as from 100K-ohms to 500K-ohms.

Additionally, the optical decoupling device maintains electrical isolation while providing its control capability. Electrical isolation is critical for maintaining safe amplifier operation, as contact with previously mentioned normal operating electrical voltages inside a tube amplifier are dangerous, and can be fatal.

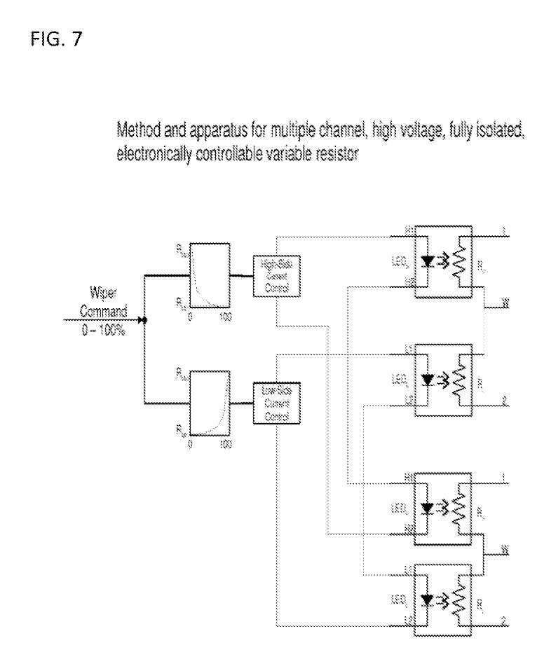

FIG. 7 details the optical decoupling device in a multi-channel configuration. Here, the optical coupling device is configured in a way that two pairs of series connected light sensitive resistors are connected so that the high-side LEDs are driven by a single current control, and the low-side LEDs are driven by another single current control. This is desirable to reduce current control circuitry, and thus cost, when it is beneficial to slave two or more optical decoupling devices to the same current control. It is common to find dual potentiometers in tube amplifiers where two discrete potentiometer sections, completely separate electrically, are connected together and operate on the same input shaft thereby slaving the functions of both potentiometer sections to the one input shaft. The multi-channel optical decoupling device replaces such a dual potentiometer. The benefits of the single channel optical decoupling device are readily apparent to any familiar in the art in the multi-channel configuration.

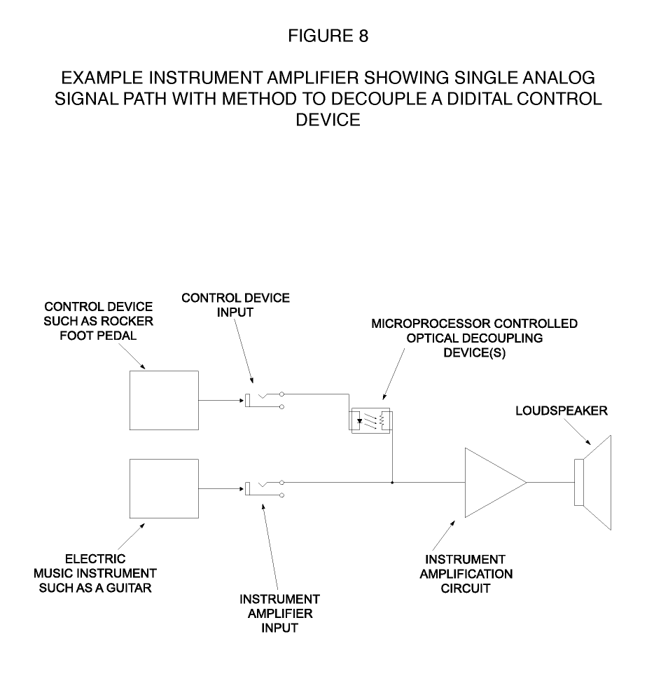

FIG. 8 details an example of how the optical decouplers may be incorporated to control the preamplifier gain of a single channel vacuum tube instrument amplifier. In this example, a multi-channel optical decoupling device is inserted into the amplifier circuit in place of a dual potentiometer thereby providing a means to electronically control the gain of the preamplifier stage of the guitar amplifier. Both optical decoupler pairs are controlled by a single pair of current controls. In this example, the preamplifier control appears to the digital control system, and the musician, as though the preamplifier had only one control.

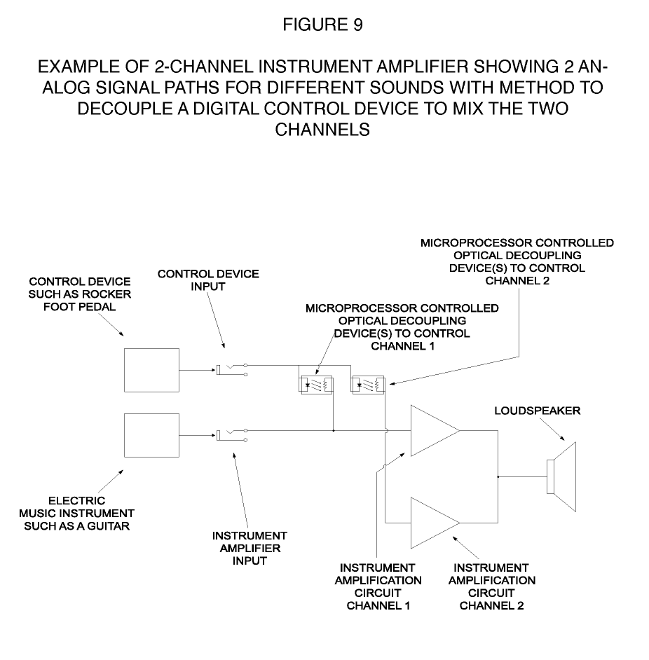

FIG. 9 details an example of how the optical decouplers may be incorporated to control the post-preamplifier mixing of a dual-channel vacuum tube instrument amplifier. In this example, the same reference tube amplifier circuit is modified to incorporate two preamplifier circuits that are then connected via multi-channel optical decouplers to provide electronic means of panning, or mixing, the two preamplifier output signals prior to insertion into the main amplifier stage. A possible use for an amplifier so equipped would be to adjust preamplifier A to a “clean” sound, and preamplifier B to a clipped or “dirty” sound, and then set the master volume to the desired level. The musician is then able to smoothly adjust the sound of the guitar through an amplifier so equipped from fully clean to fully dirty, or practically anywhere in between, simply by rocking a volume pedal. Likewise, other digital control protocols may be employed, such as MIDI, control software, or any other digital control method.

What is claimed is:

1. Method for controlling music instrument amplifiers (vacuum tube or transistor based) using digitally or electronically controllable electrical isolation devices.

2. From the first claim, control circuits using LED isolators, optical decouplers, or other digitally or electronically controllable electrical isolation devices in music instrument amplifiers.

3. From the first claim, control circuits and/or methods using LED isolators or optical decouplers to achieve electrical isolation from high voltage signals in a music instrument amplifier anywhere in the signal path, such as gain controls, tone stack or circuit, e.g., circuit, presence control, etc.

4. From the first claim, simultaneous control of multiple music instrument amplifiers to achieve stereo or multi-channel operation of music instrument amplifiers using the aforementioned method or methods.

5. From the first claim, methods to dynamically control music instrument amplifiers using analog devices such as foot pedals, which then interface with isolation or decoupling devices such as LED isolators or optical decouplers.

6. From the first claim, digital control methods such as studio controllers, MIDI controllers, show control software or similar to actuate control of isolation or decoupling devices such as LED isolators or optical decouplers in music instrument amplifiers.

7. From the first claim, control circuits and/or methods using LED isolators or optical decouplers to achieve electrical isolation from signals in a tube guitar amplifier in the power amplifier stage.

8. From the first claim, a method for changing potentiometer resistance values digitally with no alteration to hardware using LED isolators or optical decouplers.
